(19) United States
(12) Patent Application Publication
(10) Pub. No.: US 2026/0215144 A1
(43) Pub. Date: Jul. 23, 2026

(54) METHOD OF FORMING METAL PATTERN, DISPLAY DEVICE, AND ELECTRONIC DEVICE INCLUDING THE DISPLAY DEVICE

(71) Applicant: SAMSUNG DISPLAY CO., LTD., YONGIN-SI (KR)

(72) Inventors: JOON WOO BAE, Yongin-si (KR); INYOUNG JUNG, Yongin-si (KR); JAEWOO JEONG, Yongin-si (KR)

(21) Appl. No.: 19/334,039

(22) Filed: Sep. 19, 2025

(30) Foreign Application Priority Data
Jan. 22, 2025 (KR) 10-2025-0009435

(51) Int. Cl. H10K 71/00; H10K 59/12; H10K 59/131

(52) U.S. Cl. CPC H10K 71/621; H10K 59/1201; H10K 59/131

(57) ABSTRACT

A method of forming a metal pattern includes forming a resin pattern on a substrate, immersing the substrate in a solution, placing a magnet under the substrate, and precipitating metal nanoparticles dissolved within the solution on the substrate, over the resin pattern to form the metal pattern.

### CROSS-REFERENCE TO RELATED APPLICATION(S)

This application claims priority under 35 U.S.C § 119 to Korean Patent Application No. 10-2025-0009435, filed on Jan. 22, 2025, in the Korean Intellectual Property Office, the disclosure of which is incorporated by reference herein in its entirety.

### TECHNICAL FIELD

The present disclosure relates to a method of forming a metal pattern, a display device including the metal pattern, and an electronic device including the display device.

### DISCUSSION OF THE RELATED ART

A semiconductor device, a display device, an electronic device, and/or the like may include metal patterns (or metal thin films). A method of forming the metal patterns may include a chemical vapor deposition (“CVD”), an atomic layer deposition (“ALD”), a sputtering process, and/or the like. The metal patterns may be formed on a substrate or an insulating layer.

A high-resolution display device such as a head mounted display device and/or the like may have several practical applications, including in the context of virtual reality (“VR”) or augmented reality (“VR”). A micro display may be used in a high-resolution display device, and the micro display may include an organic light-emitting diode on silicon (“OLEDos”) structure.

### SUMMARY

According to several embodiments of the present disclosure, a method of forming a metal pattern is provided.

Several embodiments of the present disclosure provide a high-resolution display device using the method of forming the metal pattern.

Several embodiments of the present disclosure provide an electronic device including the display device.

According to an embodiment, a method of forming a metal pattern includes forming a resin pattern on a substrate, immersing the substrate in a solution, and placing a magnet under the substrate.

In several embodiments, the solution may include a solvent, and the metal nanoparticles dispersed in the solvent.

In several embodiments, at least some of the metal nanoparticles may penetrate into the resin pattern when the magnet is placed under the substrate.

In several embodiments, each of the metal nanoparticles may include at least one metal selected from a group consisting of iron (“Fe”), cobalt (“Co”), and nickel (“Ni”).

In several embodiments, each of the metal nanoparticles may be coated with a surfactant.

In several embodiments, a metal pattern may be formed on the resin pattern by placing the magnet under the substrate.

In several embodiments, the method may include removing the magnet from under the substrate, a metal layer may be formed on the substrate by placing the magnetic member, and a portion of the metal layer spaced apart from the resin pattern in a plan view may be removed by removing the magnet from under the substrate.

In several embodiments, the method may include forming an insulating layer on the substrate, and the forming of the resin pattern on the substrate may include forming the resin pattern on the insulating layer.

In several embodiments, the forming of the resin pattern on the insulating layer may include forming a contact hole in the insulating layer and forming the resin pattern. The resin pattern may fill at least a portion of the contact hole.

In several embodiments, a metal pattern may be formed to fill at least a portion of the contact hole by placing the magnet under the substrate.

According to an embodiment, a display device includes a first insulating layer on a substrate, the first insulating layer including a first contact hole, a resin pattern filling at least a portion of the first contact hole, a first contact electrode covering the resin pattern, a second insulating layer covering the first contact electrode, and a light-emitting element on the second insulating layer.

In several embodiments, the first contact electrode may cover an upper surface of the resin pattern disposed in at least the portion of the first contact hole.

In several embodiments, the first contact electrode may be fixed on the substrate using the resin pattern.

In several embodiments, the substrate may include a first contact area, and the first contact electrode may be fixed to the first contact area using the resin pattern.

In several embodiments, at least some of metal nanoparticles included in the first contact electrode may penetrate into the resin pattern.

In several embodiments, each of the metal nanoparticles may include at least one metal selected from a group consisting of iron (“Fe”), cobalt (“Co”), and nickel (“Ni”).

In several embodiments, each of the metal nanoparticles may be coated with a surfactant.

According to an embodiment, an electronic device includes a display device, a processor configured to drive the display device, and a memory configured to store data information. The display device includes a first insulating layer on a substrate, the first insulating layer including a first contact hole, a resin pattern filling at least a portion of the first contact hole, a first contact electrode covering the resin pattern, a second insulating layer covering the first contact electrode, and a first light-emitting element on the second insulating layer

In several embodiments, the first contact electrode may be fixed on the substrate using the resin pattern.

In several embodiments, at least some of metal nanoparticles included in the first contact electrode may penetrate into the resin pattern.

### BRIEF DESCRIPTION OF THE DRAWINGS

The above and other features of the disclosure will become more apparent from the following description of the embodiments, taken in conjunction with the accompanying drawings, in which:

FIG. 1 is a flowchart illustrating a method of forming a metal pattern, according to an embodiment of the present disclosure.

FIGS. 2A, 2B, and 2C are front views illustrating steps of forming a resin pattern on a substrate, according to an embodiment of the present disclosure.

FIG. 3 is a front view illustrating an example of a step of immersing a substrate in a solution, according to an embodiment of the present disclosure.

FIG. 4 is a front view illustrating a step of placing a magnet under a substrate, according to an embodiment of the present disclosure.

FIG. 5 is a front view illustrating a step of removing a magnet, according to an embodiment of the present disclosure.

FIG. 6 is a front view illustrating an enlarged view of an area X of FIG. 5, according to an embodiment of the present disclosure.

FIGS. 7 and 8 are front views illustrating that a metal pattern is formed on a substrate, according to several embodiments of the present disclosure

FIG. 9 is a front view illustrating an example of a step of immersing a substrate in a solution and a step of placing a magnet under the substrate, according to an embodiment of the present disclosure.

FIG. 10 is a front view illustrating a step of forming a metal pattern on a substrate, according to an embodiment of the present disclosure.

FIG. 11 is a plan view illustrating a display device including a metal pattern, according to an embodiment of the present disclosure.

FIG. 12 is a cross-sectional view of the display device of FIG. 11 taken along line I-I′, according to an embodiment of the present disclosure.

FIG. 13 is a cross-sectional view illustrating an enlarged view of an area Y of FIG. 12, according to an embodiment of the present disclosure.

FIG. 14 is a block diagram illustrating an electronic device, according to an embodiment of the present disclosure.

FIG. 15 shows examples of electronic devices, according to several embodiments of the present disclosure.

### DETAILED DESCRIPTION OF THE EMBODIMENTS

Hereinafter, the present invention will be described more fully with reference to the accompanying drawings, in which several embodiments of the present invention are shown. In the following description, portions necessary for understanding an operation according to the disclosure may be described, and descriptions of other portions may be omitted. In addition, the disclosure may be embodied in other forms without being necessarily limited to the embodiments described herein. The embodiments described herein are provided so that this disclosure will be thorough and complete, and will fully convey the scope of the invention to those skilled in the art.

Terms such as “below”, “at the bottom”, “lower”, “below”, “above”, “on top”, “on the top”, “on”, etc., are used to explain a relationship between components shown in the drawings. The terms are relative concepts and are explained based on the direction indicated in the drawings. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under” may include both directions of “on” and “under”.

Same reference numerals are used for the same components in the drawings, and redundant descriptions of the same components may be omitted. To the extent that an element is not described in detail with respect to a figure, it may be understood that the element is at least similar to a corresponding element that has been described elsewhere within the present disclosure.

Traditionally, to form a metal pattern on a substrate, the metal layer including copper may be formed on the substrate, the photoresist pattern may be formed on the metal layer, and a portion of the metal layer may be removed through a wet etching process to form the metal pattern. When the metal pattern is formed through the wet etching process, it might be difficult to control or adjust skew. Thus, the metal pattern might not be suitable for a high-resolution display device.

To resolve these challenges, a method to form a metal pattern on the substrate is disclosed. According to an embodiment of the present disclosure, a metal pattern may be formed by forming a resin pattern on a substrate, and submersing the substrate with resin pattern in a solvent. A magnet may be placed under the substrate and subsequently removed. Accordingly, the metal pattern may be formed on the substrate. The disclosed method reduces the difficulty in controlling skew. The metal pattern, according to several embodiments of the present disclosure, may be suitable for a high-resolution display device.

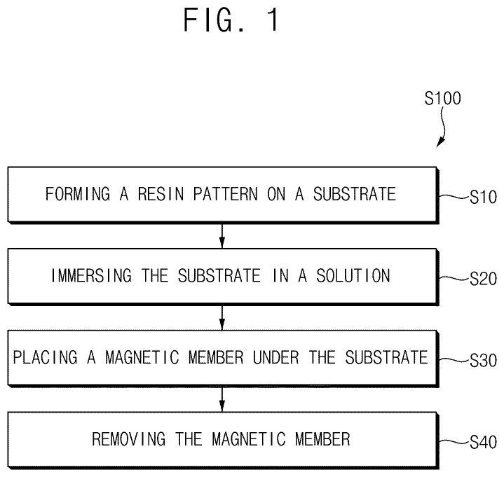

FIG. 1 is a flowchart illustrating a method of forming a metal pattern according to an embodiment.

Referring to FIG. 1, a method S100 may be a method for forming metal patterns included in a semiconductor device, a display device, an electronic device, and/or the like. For example, the display device may include a pixel circuit and a light-emitting element electrically connected to the pixel circuit. The pixel circuit may include a substrate and transistors located on the substrate. Each of the transistors may include metal patterns or metal thin films. For example, the method S100 may be a method for forming the metal patterns included in transistors. However, this disclosure is not necessarily limited thereto, and the method S100 may be applied to methods for forming all metal patterns included in the semiconductor device, the display device, the electronic device, and/or the like.

According to several embodiments, the method S100 for forming a metal pattern may include the step of forming a resin pattern on a substrate S10, the step of immersing the substrate in a solution S20, the step of placing a magnet under the substrate S30, and the step of removing the magnet S40.

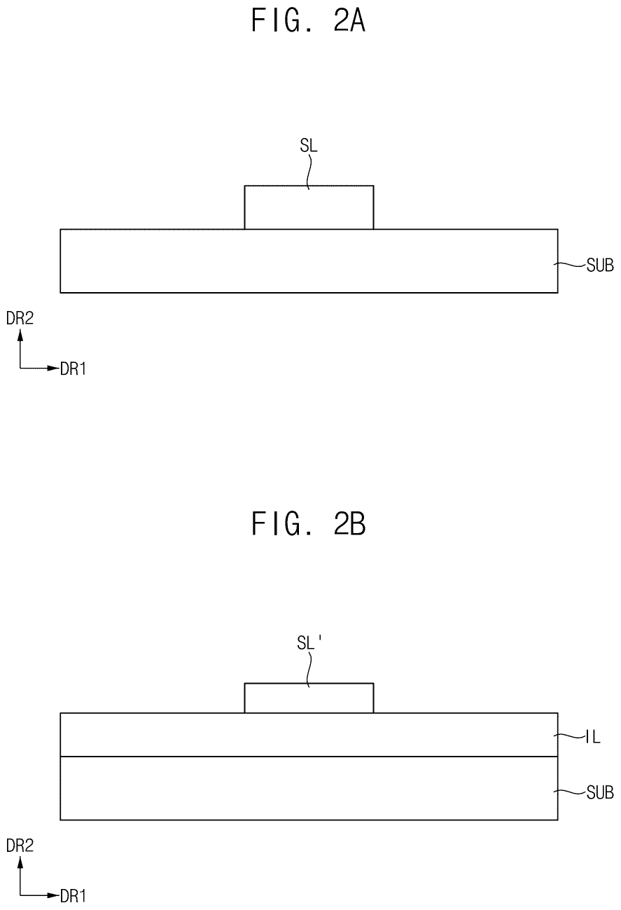

FIGS. 2A, 2B, and 2C are front views illustrating a step of forming a resin pattern on a substrate.

Specifically, FIG. 2A is a front view illustrating a step of forming a resin pattern SL on a substrate SUB, according to an embodiment of the present disclosure. FIG. 2B is a front view illustrating a step of forming a resin pattern SL′ on an insulating layer IL, according to an embodiment of the present disclosure. FIG. 2C is a front view illustrating a step of forming a resin pattern SL″ in a contact hole CNT formed in the insulating layer IL, according to an embodiment of the present disclosure.

Referring to FIGS. 1 and 2A, the resin pattern SL may be formed on the substrate SUB. The substrate SUB may be a base of the semiconductor device, the display device, the electronic device, and/or the like. In an embodiment, the substrate SUB may be a silicon substrate. For example, the substrate SUB may be a p-type silicon substrate or an n-type silicon substrate. For example, “p” may refer to a hole, and “n” may refer to an electron. However, this disclosure is not necessarily limited thereto, and in an embodiment, the substrate SUB may be made of a transparent resin substrate. Examples of the transparent resin substrate may include a polyimide substrate and/or the like. For example, the polyimide substrate may include a first organic layer, a first barrier layer, a second organic layer, and/or the like. In some embodiments, the substrate SUB may also include a quartz substrate (e.g., a synthetic quartz substrate, an F-doped quartz substrate), a calcium fluoride substrate, a soda lime glass substrate, a non-alkali glass substrate, and/or the like.

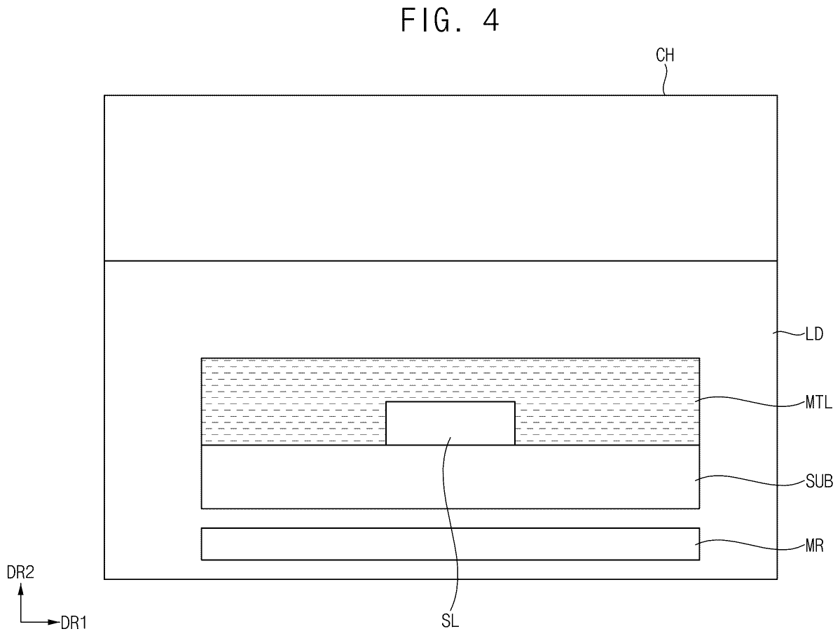

A target area may be defined on the substrate SUB. A metal pattern (e.g., a metal pattern MTP of FIG. 5) may be formed in the target area. The resin pattern SL may be formed in the target area on the substrate SUB. For example, the resin pattern SL may be formed in an area where the metal pattern is desired to be formed. The metal pattern may be adsorbed onto or fixed to the substrate SUB using the resin pattern SL. For example, the metal pattern may be adsorbed onto or fixed to the substrate SUB by the resin pattern SL. For example, the resin pattern SL may include phenolic resin, polyacrylates resin, polyimides resin, polyamides resin, siloxane resin, epoxy resin, polyethylene terephthalate, polymethyl methacrylate, polyurethane, polycarbonate, polyvinyl alcohol-based resin, and/or the like. These materials may be used alone or in combination with each other. However, this disclosure is not necessarily limited thereto, and the resin pattern SL may include various materials that enable the metal pattern to be adsorbed onto the substrate SUB.

As illustrated in FIG. 2A, the resin pattern SL may be formed on the substrate SUB. However, this disclosure is not necessarily limited thereto, and the resin pattern SL may be formed on various components including the substrate SUB.

Referring to FIG. 2B, for example, an insulating layer IL may be formed on the substrate SUB, and a resin pattern SL′ may be formed on the insulating layer IL. In an embodiment, the insulating layer IL may be an inorganic insulating layer. For example, the insulating layer IL may include inorganic materials such as silicon oxide (“SiOₓ”), silicon nitride (“SiNx”), silicon carbide (“SiCₓ”), silicon oxynitride (“SiOₓN_{y}”), and silicon oxycarbide (“SiOₓC_{y}”). These materials may be used alone or in combination with each other. However, this disclosure is not necessarily limited thereto, and the insulating layer IL may be an organic insulating layer. For example, the insulating layer IL may include organic materials such as phenolic resin, polyacrylates resin, polyimides resin, polyamides resin, siloxane resin, epoxy resin, and/or the like. These materials may be used alone or in combination with each other.

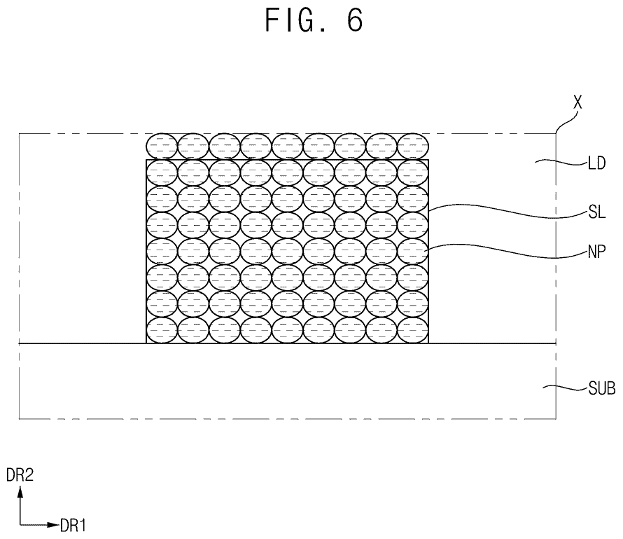

In some embodiments, a target area may be defined on the insulating layer IL, and a metal pattern (e.g., a metal pattern MTP′ of FIG. 7) may be formed in the target area. The metal pattern may be adsorbed onto or fixed to the insulating layer IL using the resin pattern SL′. For example, the metal pattern may be adsorbed onto or fixed to the insulating layer IL by the resin pattern SL′. The resin pattern SL′ and the resin pattern SL of FIG. 2A may include substantially a same material.

Referring to FIG. 2C, in some embodiments, an insulating layer IL may be formed on the substrate SUB, a contact hole CNT may be formed in the insulating layer IL, and a resin pattern SL″ may be formed to fill at least a portion of the contact hole CNT. The contact hole CNT may expose at least a portion of an upper surface of an electrode PT. The electrode PT may be a component located on the substrate SUB. For example, the electrode PT may be an electrode included in the semiconductor device, the display device, the electronic device, and/or the like. For example, the electrode PT may be an electrode included in the pixel circuit. In several embodiments, the resin pattern SL″ may cover the upper surface of the electrode PT exposed by the contact hole CNT. However, this disclosure is not necessarily limited thereto, and when the substrate SUB is a silicon substrate, the electrode PT may be omitted. For example, at least a portion of the silicon substrate may be exposed by the contact hole CNT.

For example, the electrode PT may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other. However, this disclosure is not necessarily limited thereto, and in an embodiment, the electrode PT may be omitted.

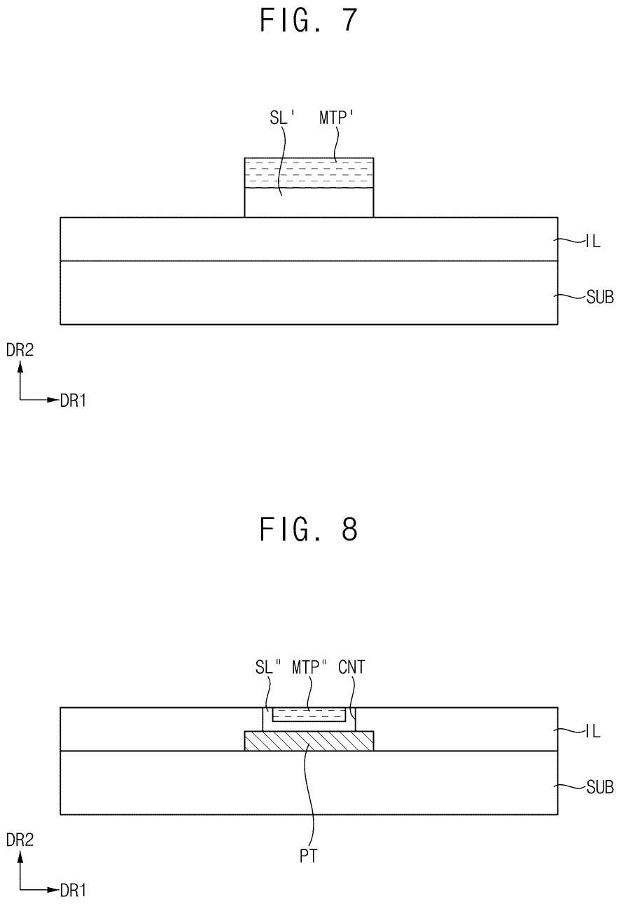

A target area may be defined in the contact hole CNT, and a metal pattern (e.g., a metal pattern MTP″ of FIG. 8) may be formed in the target area. The metal pattern may be adsorbed onto or fixed to the electrode PT using the resin pattern SL″. For example, the metal pattern may be adsorbed onto or fixed to the electrode PT by the resin pattern SL″. The resin pattern SL″ and the resin pattern SL of FIG. 2A may include substantially a same material.

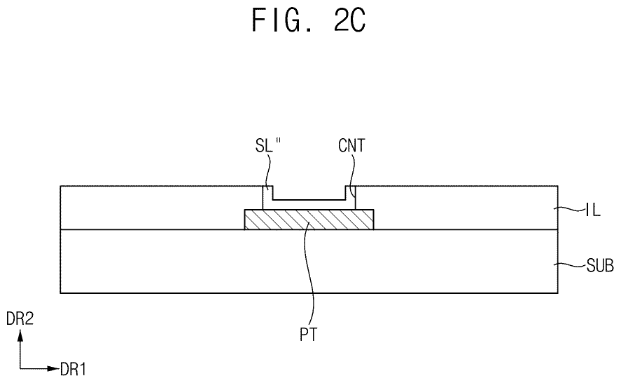

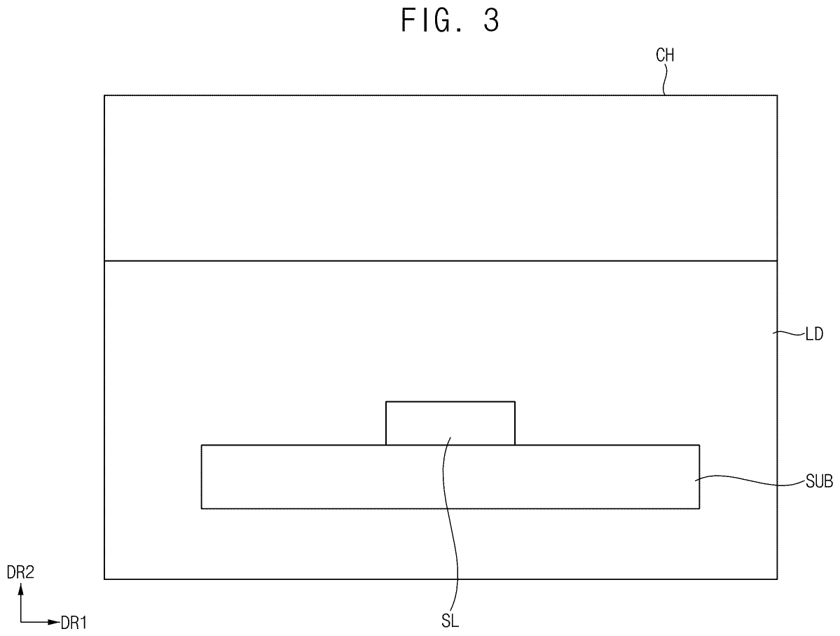

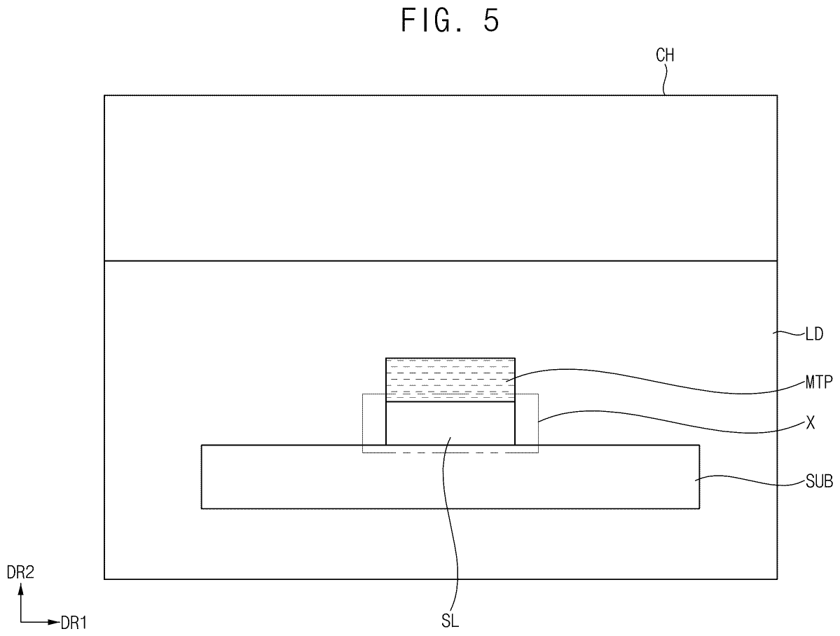

FIG. 3 is a front view illustrating an example of a step of immersing a substrate in a solution. FIG. 4 is a front view illustrating a step of placing a magnet under a substrate. FIG. 5 is a front view illustrating a step of removing a magnet. FIG. 6 is a front view illustrating an enlarged view of an area X of FIG. 5.

Referring to FIGS. 1 and 3, the substrate SUB and the resin pattern SL may be placed in a chamber CH. The chamber CH may include a solution LD. The substrate SUB and the resin pattern SL may be immersed in the solution LD. In an embodiment, the solution LD may include a solvent and metal nanoparticles. For example, the solution LD may include metal nanoparticles NP of FIG. 6 dispersed in the solvent. In an embodiment, each of the metal nanoparticles may include a ferromagnetic material. For example, each of the metal nanoparticles may include iron (“Fe”), cobalt (“Co”), nickel (“Ni”), and/or the like. These materials may be used alone or in combination with each other. In an embodiment, each of the metal nanoparticles may include an alloy of the ferromagnetic material and a metal. Examples of the metal may include silver (“Ag”), molybdenum (“Mo”), aluminum (“Al”), tungsten (“W”), copper (“Cu”), chromium (“Cr”), titanium (“Ti”), tantalum (“Ta”), platinum (“Pt”), scandium (“Sc”), and/or the like. These materials may be used alone or in combination with each other. Depending on materials included in each of the metal nanoparticles, materials included in a metal layer (e.g., a metal layer MTL of FIG. 4) and a metal pattern (e.g., a metal pattern MTP of FIG. 5) may be determined. For example, when each of the metal nanoparticles includes an alloy of iron (“Fe”) and copper (“Cu”), the metal layer and the metal pattern may include an alloy of iron and copper. In an embodiment, each of the metal nanoparticles may be coated with a surfactant. Accordingly, the metal nanoparticles might not tangle or agglomerate. For example, the surfactant may include a salicylic acid-based compound such as lithium salicylate, sodium salicylate, potassium salicylate, and/or the like. However, this disclosure is not necessarily limited thereto, and the surfactant may include various materials.

Referring to FIGS. 1 and 4, a magnet MR may be placed under the substrate SUB. In an embodiment, the magnet MR may be placed under an entire area of the substrate SUB. For example, the magnet MR may entirely overlap the substrate SUB in a plan view. The magnet MR may include an electromagnet or a permanent magnet. As the magnet MR is placed under the substrate SUB, a metal layer MTL may be formed on the substrate SUB. As described above, the solution LD may include the metal nanoparticles, and each of the metal nanoparticles may include a ferromagnetic material. As the magnet MR is placed under the substrate SUB, the metal nanoparticles may be precipitated on a surface of the substrate SUB. For example, the metal nanoparticles may be precipitated on an upper surface of the substrate SUB. Accordingly, the metal layer MTL may be formed. The metal layer MTL may cover the upper surface of the substrate SUB. In several embodiments, the metal layer MTL may cover at least a portion of the resin pattern SL.

In an embodiment, the magnet MR may be spaced apart from the resin pattern SL. For example, the magnet MR may be spaced apart from the resin pattern SL, and the substrate SUB may be located between the magnet MR and the resin pattern SL.

In an embodiment, a first direction DR1 and a second direction DR2 crossing the first direction DR1 may be defined. For example, the second direction DR2 may be substantially perpendicular to the first direction DR1. However, this disclosure is not necessarily limited thereto, and the second direction DR2 may form an acute angle or an obtuse angle with the first direction DR1.

Referring to FIGS. 1, 4, and 5, the magnet MR may be removed. As the magnet MR is removed, at least a portion of the metal layer MTL may be removed. For example, a portion of the metal layer MTL that is spaced apart from the resin pattern SL in a plan view may be removed. A portion of the metal layer MTL that overlaps the resin pattern SL in a plan view may be adsorbed onto or fixed to the substrate SUB using the resin pattern SL. For example, a portion of the metal layer MTL that overlaps the resin pattern SL in a plan view may be adsorbed onto or fixed to the substrate SUB by the resin pattern SL. Accordingly, a metal pattern MTP may be formed. The metal pattern MTP may overlap the resin pattern SL in a plan view. For example, as the resin pattern SL is formed in the target area on the substrate SUB, the metal pattern MTP may be formed in the target area on the substrate SUB.

Referring further to FIG. 6, the magnet MR may be placed under the substrate SUB. Accordingly, the metal nanoparticles NP may be precipitated on the upper surface of the substrate SUB, and at least some of the metal nanoparticles NP may penetrate into the resin pattern SL. As described above, the magnet MR may be removed. Accordingly, among the metal nanoparticles NP precipitated on the upper surface of the substrate SUB, the metal nanoparticles NP that are spaced apart from the resin pattern SL in a plan view may be removed from the upper surface of the substrate SUB. In addition, the metal nanoparticles NP that penetrate into the resin pattern SL and the metal nanoparticles NP that are located on the resin pattern SL may be adsorbed onto or fixed to the upper surface of the substrate SUB.

The metal pattern MTP may be formed without performing a chemical vapor deposition (“CVD”), an atomic layer deposition (“ALD”), a sputtering process, and/or the like. For example, according to an embodiment of this disclosure, the metal pattern MTP may be formed through the resin pattern SL formed on the substrate SUB and the magnet MR placed under the substrate SUB. Accordingly, a process of forming the metal pattern MTP on the substrate SUB may be simplified.

In addition, a method of forming a metal pattern according to a comparative example may include forming a metal layer on the substrate SUB, forming a photoresist pattern on the metal layer, and forming a metal pattern by removing a portion of the metal layer through an etching process. For example, to form the metal pattern on the substrate SUB, the metal layer including copper may be formed on the substrate SUB, the photoresist pattern may be formed on the metal layer, and a portion of the metal layer may be removed through a wet etching process to form the metal pattern. When the metal pattern is formed through the wet etching process, it might be difficult to control or adjust skew. Accordingly, the metal pattern might not be suitable for a high-resolution display device.

According to an embodiment of the present disclosure, the metal pattern MTP may be formed through the resin pattern SL and the magnet MR. For example, the metal pattern MTP may be formed using the resin pattern SL and the magnet MR. Accordingly, when the metal pattern MTP is formed, an issue of difficulty in controlling skew might not occur. Accordingly, the metal pattern MTP may be suitable for a high-resolution display device.

FIGS. 7 and 8 are front views illustrating that a metal pattern is formed on a substrate, according to some embodiments of the present disclosure.

Specifically, FIG. 7 illustrates that a metal pattern MTP′ is formed on the insulating layer IL. FIG. 8 illustrates that a metal pattern MTP″ is formed in the contact hole CNT, and the contact hole CNT is formed in the insulating layer IL.

Referring to FIG. 7, as described above with reference to FIG. 2B, the insulating layer IL may be formed on the substrate SUB. For example, according to the method (e.g., the method S100 of FIG. 1) of forming the metal pattern according to an embodiment, a resin pattern SL′ may be formed on the insulating layer IL, and the metal pattern MTP′ may be formed on the resin pattern SL′. The metal pattern MTP′ and the metal pattern MTP of FIG. 5 may include substantially a same material.

The metal pattern MTP′ may be formed without performing a chemical vapor deposition (“CVD”), an atomic layer deposition (“ALD”), a sputtering process, and/or the like. For example, according to an embodiment of the present disclosure, the metal pattern MTP′ may be formed through the resin pattern SL′ formed on the insulating layer IL and the magnet (e.g., the magnet MR of FIG. 4) placed under the substrate SUB. Accordingly, a process of forming the metal pattern MTP′ on the insulating layer IL may be simplified.

In addition, a method of forming a metal pattern according to a comparative example may include forming a metal layer on the insulating layer IL, forming a photoresist pattern on the metal layer, and forming a metal pattern by removing a portion of the metal layer through an etching process. For example, to form the metal pattern on the insulating layer IL, the metal layer including copper may be formed on the insulating layer IL, the photoresist pattern may be formed on the metal layer, and a portion of the metal layer may be removed through a wet etching process to form the metal pattern. When the metal pattern is formed through the wet etching process, it may be difficult to control or adjust skew. Accordingly, the metal pattern might not be suitable for a high-resolution display device.

According to an embodiment of the present disclosure, the metal pattern MTP′ may be formed through the resin pattern SL′ and the magnet. Accordingly, when the metal pattern MTP′ is formed, an issue of difficulty in controlling skew might not occur. Accordingly, the metal pattern MTP′ may be suitable for a high-resolution display device.

Referring to FIG. 8, as described above with reference to FIG. 2C, the insulating layer IL may be formed on the substrate SUB, and the contact hole CNT may be formed in the insulating layer IL. For example, according to the method (e.g., the method S100 of FIG. 1) of forming the metal pattern according to an embodiment, a resin pattern SL″ may be formed to fill at least a portion of the contact hole CNT. Additionally, a metal pattern MTP″ may be formed to fill at least a portion of the contact hole CNT. For example, the metal pattern MTP″ may be formed to fill at least a portion of the contact hole CNT by placing the magnet (e.g., the magnet MR of FIG. 4) under the substrate SUB. For example, the metal pattern MTP″ may be surrounded by the resin pattern SL″ in a plan view. The metal pattern MTP″ and the metal pattern MTP of FIG. 5 may include substantially a same material.

The metal pattern MTP″ may be formed without performing a chemical vapor deposition (“CVD”), an atomic layer deposition (“ALD”), a sputtering process, and/or the like. For example, according to an embodiment of the present disclosure, the metal pattern MTP″ may be formed using the resin pattern SL″. The resin pattern SL″ may be formed to fill the contact hole CNT when the magnet (e.g., the magnet MR of FIG. 4) is placed under the substrate SUB. Accordingly, a process of forming the metal pattern MTP″ that fills the contact hole CNT may be simplified.

In a comparative example, when a metal pattern filling the contact hole CNT is formed through the chemical vapor deposition (“CVD”), the atomic layer deposition (“ALD”), the sputtering process, and/or the like, the metal pattern may include an overhang structure, voids, and/or the like. According to an embodiment of the present disclosure, when the metal pattern MTP″ is formed to fill the contact hole CNT through the resin pattern SL″ and the magnet, the metal pattern MTP″ may be easily formed on the substrate SUB without including an overhang structure, voids, and/or the like. In several embodiments, as resolution of a display device increases, width of the contact hole CNT in the first direction DR1 may decrease, and height in the second direction DR2 may increase. For example, as the resolution of the display device increases, aspect ratio of the contact hole CNT may increase. Accordingly, as the resolution of the display device increases, it may become difficult for the contact hole CNT to be completely filled with the metal pattern MTP″. For example, as the resolution of the display device increases, probability that the metal pattern MTP″ filled in the contact hole CNT includes an overhang structure, voids, and/or the like may increase. According to an embodiment of the present disclosure, the metal pattern MTP″ may be easily formed in the contact hole CNT without including an overhang structure, voids, and/or the like. Accordingly, the metal pattern MTP″ may be suitable for a high-resolution display device.

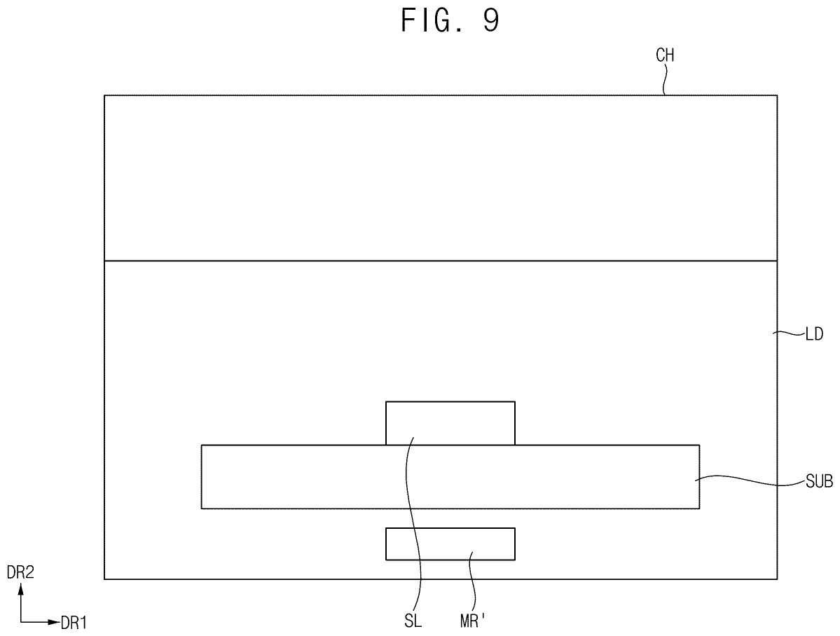

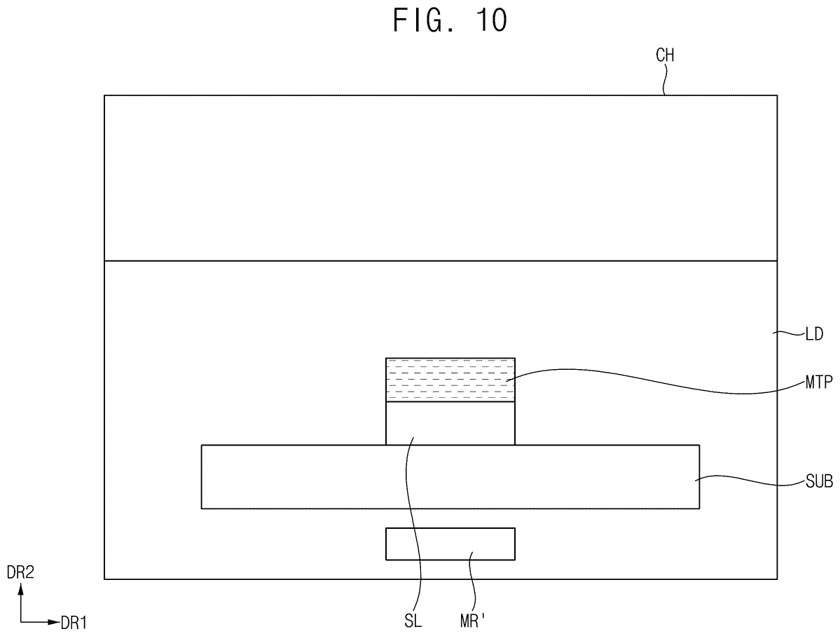

FIG. 9 is a front view illustrating an example of a step of immersing a substrate in a solution and a step of placing a magnet under the substrate. FIG. 10 is a front view illustrating a step of forming a metal pattern on a substrate.

Components illustrated in FIGS. 9 and 10 may differ from components illustrated in FIG. 4 only in terms of the magnet MR. Therefore, redundant descriptions may be omitted. For example, the magnet MR′ illustrated in FIGS. 9 and 10 may differ from the magnet MR′ illustrated in FIG. 4. To the extent that an element is not described in detail with respect to a figure, it may be understood that the element is at least similar to a corresponding element that has been described elsewhere within the present disclosure.

Referring to FIGS. 9 and 10, the substrate SUB and the resin pattern SL may be immersed in the solution LD (e.g., the step S20 of FIG. 1). In several embodiments, a magnet MR′ may be placed under the substrate SUB (e.g., the step S30 of FIG. 1). The magnet MR′ may include an electromagnet or a permanent magnet. In an embodiment, the magnet MR′ may be placed only under a partial area of the substrate SUB. For example, as illustrated in FIGS. 9 and 10, the magnet MR′ may be placed only in a portion that overlaps the resin pattern SL in a plan view. As the magnet MR′ is placed under the substrate SUB, the metal pattern MTP may be formed on the substrate SUB. As the magnet MR′ is placed only in the portion that overlaps the resin pattern SL in a plan view, the metal nanoparticles included in the solution LD may be precipitated only in the portion that overlaps the resin pattern SL in a plan view. Therefore, in several embodiments, even if the magnet MR′ is not removed, the metal pattern MTP may be formed on the substrate SUB.

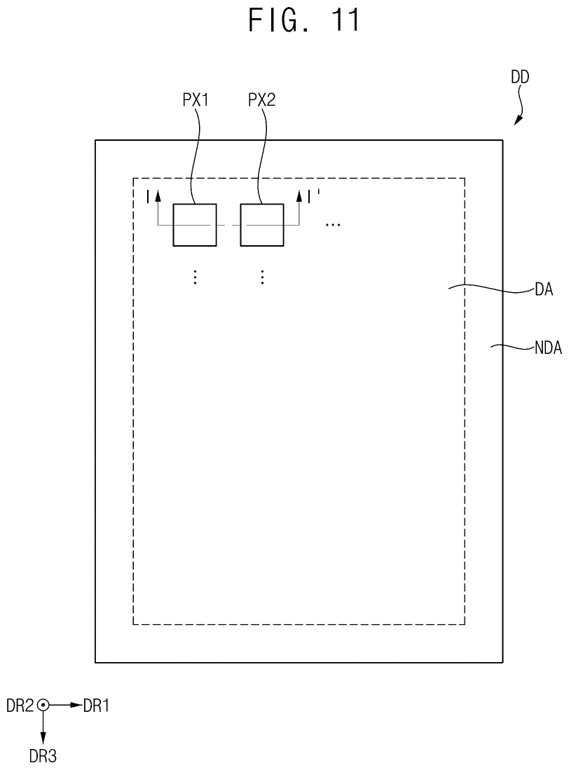

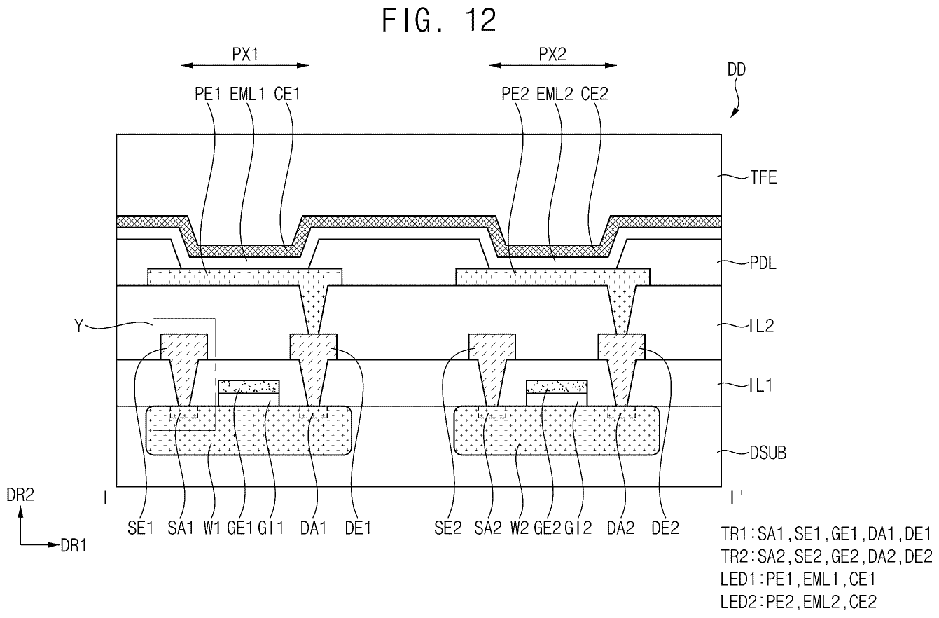

FIG. 11 is a plan view illustrating a display device including a metal pattern, according to an embodiment. FIG. 12 is a cross-sectional view of the display device of FIG. 11 taken along line I-I′.

Referring to FIG. 11, a display device DD may include a metal pattern. For example, the metal pattern may be formed using the method S100 of FIG. 1. For example, the display device DD may include a first contact electrode SE1, a second contact electrode DE1, a third contact electrode SE2, and a fourth contact electrode DE2 formed by the method of forming the metal pattern. For example, each of the first contact electrode SE1, the second contact electrode DE1, the third contact electrode SE2, and the fourth contact electrode DE2 may be formed by the method of forming the metal pattern.

The display device DD may include a display area DA and a non-display area NDA surrounding the display area DA.

The display area DA may be an area that generates light or controls transmittance of light provided from an external light source to display an image. A plurality of pixel areas may be arranged in the display area DA. For example, a first pixel area PX1 and a second pixel area PX2 may be arranged in the display area DA. Each of the plurality of pixel areas may emit light. For example, each of the first pixel area PX1 and the second pixel area PX2 may emit light.

The plurality of pixel areas may be generally arranged across the display area DA. Accordingly, the display area DA may display an image. In an embodiment, the plurality of pixel areas may be repeatedly arranged along the first direction DR1 and a third direction DR3. The third direction DR3 may cross a plane defined by the first direction DR1 and the second direction DR2. For example, the third direction DR3 may be substantially perpendicular to the plane defined by the first direction DR1 and the second direction DR2. However, this disclosure is not necessarily limited thereto, and the third direction DR3 may form an acute angle or an obtuse angle with the plane defined by the first direction DR1 and the second direction DR2. The second pixel area PX2 may be spaced apart from the first pixel area PX1 in the first direction DR1.

The non-display area NDA may surround at least a portion of the display area DA. A driver may be located in the non-display area NDA. The driver may provide a signal or voltage to the plurality of pixel areas. For example, the driver may include a data driver, a gate driver, and/or the like. In an embodiment, the non-display area NDA might not display an image.

Referring further to FIG. 12, the display device DD may include a substrate DSUB, a first insulating layer IL1, a second insulating layer IL2, a first gate insulating layer GI1, a second gate insulating layer GI2, a first transistor TR1, a second transistor TR2, a first light-emitting element LED1, a second light-emitting element LED2, a pixel defining layer PDL, and an encapsulation layer TFE.

The first transistor TR1 may include a first contact area SA1, a first contact electrode SE1, a first gate electrode GE1, a second contact area DA1, and a second contact electrode DE1. The second transistor TR2 may include a third contact area SA2, a third contact electrode SE2, a second gate electrode GE2, a fourth contact area DA2, and a fourth contact electrode DE2. The first light-emitting element LED1 may include a first pixel electrode PE1, a first light-emitting layer EML1, and a first common electrode CE1. The second light-emitting element LED2 may include a second pixel electrode PE2, a second light-emitting layer EML2, and a second common electrode CE2.

The substrate DSUB may be a base of the display device DD. The substrate DSUB may correspond to the substrate SUB of FIGS. 2A, 2B, and 2C. In an embodiment, the substrate DSUB may be a silicon substrate. For example, the substrate DSUB may be a p-type silicon substrate or an n-type silicon substrate. In this case, “p” may refer to a hole, and “n” may refer to an electron. The substrate DSUB may include a first well area W1 and a second well area W2. The first well area W1 may be a p-well or an n-well depending on a type of the first transistor TR1 and a type of the substrate DSUB. In addition, the second well area W2 may be a p-well or an n-well depending on a type of the second transistor TR2 and the type of the substrate DSUB.

The substrate DSUB may include the first contact area SA1 and the second contact area DA1. For example, the first contact area SA1 and the second contact area DA1 may be an n-type source area and an n-type drain area, respectively. However, this disclosure is not necessarily limited thereto, and the first contact area SA1 and the second contact area DA1 may be a p-type source area and a p-type drain area, respectively.

The substrate DSUB may further include the third contact area SA2 and the fourth contact area DA2. For example, the third contact area SA2 and the fourth contact area DA2 may be an n-type source area and an n-type drain area, respectively. However, this disclosure is not necessarily limited thereto, and the third contact area SA2 and the fourth contact area DA2 may be a p-type source area and a p-type drain area, respectively.

In an embodiment, the substrate DSUB may be made of a transparent resin substrate. Example of the transparent resin substrate may include a polyimide substrate. For example, the polyimide substrate may include a first organic layer, a first barrier layer, a second organic layer, and/or the like. In some embodiments, the substrate SUB may include a quartz substrate (e.g. a synthetic quartz substrate, a fluorine-doped quartz substrate), a calcium fluoride substrate, a soda lime glass substrate, a non-alkali glass substrate, and/or the like. These materials may be used alone or in combination with each other. In some embodiments, the display device DD may further include a first active pattern located in the first pixel area PX1 and a second active pattern located in the second pixel area PX2 on the substrate DSUB.

The first gate insulating layer GI1 and the second gate insulating layer GI2 may be located on the substrate DSUB. The first gate insulating layer GI1 may at least partially overlap the first well area W1 in a plan view. In addition, the second gate insulating layer GI2 may at least partially overlap the second well area W2 in a plan view.

Each of the first gate insulating layer GI1 and the second gate insulating layer GI2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first gate electrode GE1 may be located on the first gate insulating layer GI1. For example, the first gate electrode GE1 may overlap the first gate insulating layer GI1 in a plan view. The second gate electrode GE2 may be located on the second gate insulating layer GI2. For example, the second gate electrode GE2 may overlap the second gate insulating layer GI2 in a plan view.

For example, each of the first gate electrode GE1 and the second gate electrode GE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The first insulating layer IL1 may be located on the substrate DSUB. The first insulating layer IL1 may sufficiently cover the first gate electrode GE1 and the second gate electrode GE2.

For example, the first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

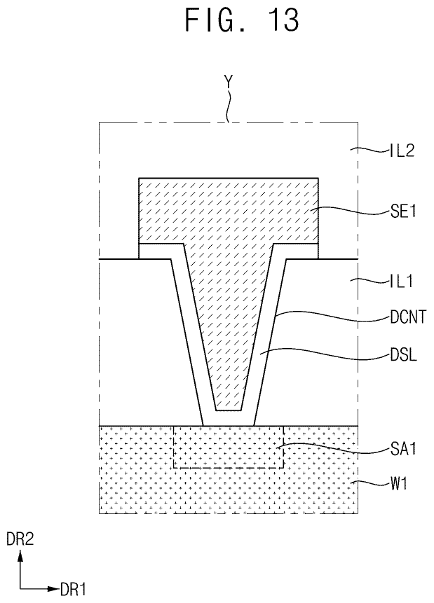

The first contact electrode SE1, the second contact electrode DE1, the third contact electrode SE2 and the fourth contact electrode DE2 may be located on the first insulating layer IL1. The first contact electrode SE1 may be connected to the first contact area SA1 through a first contact hole (e.g., a first contact hole DCNT of FIG. 13) penetrating (or, defined through) the first insulating layer IL1. In addition, the second contact electrode DE1 may be connected to the second contact area DA1 through a second contact hole penetrating (or, defined through) the first insulating layer IL1. In addition, the third contact electrode SE2 may be connected to the third contact area SA2 through a third contact hole penetrating (or, defined through) the first insulating layer IL1. In addition, the fourth contact electrode DE2 may be connected to the fourth contact area DA2 through a fourth contact hole penetrating (or, defined through) the first insulating layer IL1.

Each of the first contact electrode SE1, the second contact electrode DE1, the third contact electrode SE2 and the fourth contact electrode DE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In an embodiment, each of the first contact electrode SE1, the second contact electrode DE1, the third contact electrode SE2, and the fourth contact electrode DE2 may further include ferromagnetic particles. For example, each of the first contact electrode SE1, the second contact electrode DE1, the third contact electrode SE2, and the fourth contact electrode DE2 may further include iron (“Fe”), cobalt (“Co”), nickel (“Ni”), and/or the like. These materials may be used alone or in combination with each other.

The second insulating layer IL2 may be located on the first insulating layer IL1. In several embodiments, the second insulating layer IL2 may overlap first contact electrode SE1, the second contact electrode DE1, the third contact electrode SE2 and the fourth contact electrode DE2. For example, the second insulating layer IL2 may sufficiently cover the first contact electrode SE1, the second contact electrode DE1, the third contact electrode SE2 and the fourth contact electrode DE2.

For example, the second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first light-emitting element LED1 and the second light-emitting element LED2 may be located on the second insulating layer IL2.

The first pixel electrode PE1 and the second pixel electrode PE2 may be located on the second insulating layer IL2. The first pixel electrode PE1 may be located in the first pixel area PX1, and the second pixel electrode PE2 may be located in the second pixel area PX2.

The first pixel electrode PE1 may be connected to the second contact electrode DE1 through a fifth contact hole penetrating (or, defined through) the second insulating layer IL2. The second pixel electrode PE2 may be connected to the fourth contact electrode DE2 through a sixth contact hole penetrating (or, defined through) the second insulating layer IL2.

For example, each of the first pixel electrode PE1 and the second pixel electrode PE2 may include a metal, an alloy, a metal nitride, a conductive metal oxide, a transparent conductive material, and/or the like. These materials may be used alone or in combination with each other. In an embodiment, each of the first pixel electrode PE1 and the second pixel electrode PE2 may have a stacked structure including ITO/Ag/ITO, but this disclosure is not necessarily limited thereto. The first pixel electrode PE1 may operate as an anode of the first light-emitting element LED1, and the second pixel electrode PE2 may operate as an anode of the second light-emitting element LED2.

The pixel defining layer PDL may be located on the second insulating layer IL2. The pixel defining layer PDL may cover a side portion of the first pixel electrode PE1. For example, in the pixel defining layer PDL, a first opening exposing a portion of an upper surface of the first pixel electrode PE1 may be defined. In addition, the pixel defining layer PDL may cover a side portion of the second pixel electrode PE2. For example, in the pixel defining layer PDL, a second opening exposing a portion of an upper surface of the second pixel electrode PE2 may be defined.

For example, the pixel defining layer PDL may include an inorganic material or an organic material. In an embodiment, the pixel defining layer PDL may include an organic material such as an epoxy resin, a siloxane resin, and/or the like. These materials may be used alone or in combination with each other. In an embodiment, the pixel defining layer PDL may further include a light-blocking material including a black pigment, a black dye, and/or the like.

The first light-emitting layer EML1 may be located on the first pixel electrode PE1. For example, the first light-emitting layer EML1 may be located in the first pixel area PX1. In addition, the second light-emitting layer EML2 may be located on the second pixel electrode PE2. The second light-emitting layer EML2 may be located in the second pixel area PX2. For example, each of the first light-emitting layer EML1 and the second light-emitting layer EML2 may include an organic material that emits light of a selected color.

The first common electrode CE1 may be located on the first light-emitting layer EML1. For example, the first common electrode CE1 may be located in the first pixel area PX1. In addition, the second common electrode CE2 may be located on the second light-emitting layer EML2. For example, the second common electrode CE2 may be located in the second pixel area PX2.

For example, each of the first common electrode CE1 and the second common electrode CE2 may include a metal, an alloy, a metal nitride, a conductive metal oxide, a transparent conductive material, and/or the like. These materials may be used alone or in combination with each other. The first common electrode CE1 may operate as a cathode of the first light-emitting element LED1, and the second common electrode CE2 may operate as a cathode of the second light-emitting element LED2.

The encapsulation layer TFE may be located on the first common electrode CE1 and the second common electrode CE2. The encapsulation layer TFE may prevent impurities, moisture, and/or the like from penetrating into the first light-emitting element LED1 and the second light-emitting element LED2 from an outside of the display device DD.

For example, the encapsulation layer TFE may include at least one inorganic encapsulation layer and at least one organic encapsulation layer. For example, the inorganic encapsulation layer and the organic encapsulation layer may be alternately stacked. For example, the inorganic encapsulation layer may include silicon oxide, silicon nitride, and/or silicon oxynitride. These materials may be used alone or in combination with each other. The organic encapsulation layer may include a cured polymer such as polyacrylate.

FIG. 13 is a cross-sectional view illustrating an enlarged view of an area Y of FIG. 12.

Referring to FIGS. 12 and 13, as described above, each of the first contact electrode SE1, the second contact electrode DE1, the third contact electrode SE2, and the fourth contact electrode DE2 may be formed by the method (e.g., the method S100 of FIG. 1) of forming the metal pattern according to an embodiment.

As illustrated in FIG. 13, a resin pattern DSL may be located to fill at least a portion of a first contact hole DCNT. The resin pattern DSL may be formed by the method of forming the resin pattern on the substrate as disclosed in FIG. 1. For example, as described above with reference to FIG. 2C, the resin pattern (e.g., the resin pattern SL″ of FIG. 2C) may be formed to fill at least a portion of the contact hole (e.g., the contact hole CNT of FIG. 2C), the target area may be defined in the contact hole, and the metal pattern (e.g., the metal pattern MTP″ of FIG. 8) may be formed in the target area. The first contact electrode SE1 may substantially correspond to the metal pattern MTP″ of FIG. 8, the first contact hole DCNT may substantially correspond to the contact hole CNT of FIG. 2C, and the resin pattern DSL may substantially correspond to the resin pattern SL″ of FIG. 2C. FIG. 13 may illustrate an example in which the electrode PT of FIG. 2C is omitted and at least a portion of the substrate DSUB is exposed by the contact hole DCNT.

The first contact electrode SE1 may fill the first contact hole DCNT. The first contact electrode SE1 may be located on the resin pattern DSL, overlapping the resin pattern DSL. For example, the first contact electrode SE1 may cover the resin pattern DSL. The first contact electrode SE1 may cover an upper surface of the resin pattern DSL in the first contact hole DCNT. The first contact electrode SE1 may be adsorbed onto or fixed to the substrate DSUB by the resin pattern DSL. For example, the first contact electrode SE1 may be adsorbed onto or fixed to the first well area W1 by the resin pattern DSL. For example, the first contact electrode SE1 may be adsorbed onto or fixed to the first contact area SA1 by the resin pattern DSL.

As some of the metal nanoparticles NP of FIG. 6 penetrate into the resin pattern SL of FIG. 6, some of the metal nanoparticles included in the first contact electrode SE1 may penetrate into the resin pattern DSL. For example, when each of the metal nanoparticles included in the first contact electrode SE1 includes an alloy of copper and a ferromagnetic material, the alloy of copper and the ferromagnetic material may penetrate into the resin pattern DSL. The ferromagnetic material may include iron, cobalt, nickel, and/or the like. These materials may be used alone or in combination with each other. In an embodiment, each of the metal nanoparticles included in the first contact electrode SE1 may be coated with a surfactant.

Referring to FIG. 13, although the method of forming the first contact electrode SE1 and a structure of the first contact electrode SE1 have been described above, this disclosure is not necessarily limited thereto, and each of the second contact electrode DE1, the third contact electrode SE2, and the fourth contact electrode DE2 may be formed through substantially a same method as the first contact electrode SE1 and may have substantially a same structure as the first contact electrode SE1.

FIG. 12 illustrates an example in which the first pixel electrode PE1 and the second pixel electrode PE2 are located on the second insulating layer IL2. However, this disclosure is not necessarily limited thereto, and a first connection electrode and a second connection electrode may be located on the second insulating layer IL2. For example, a third insulating layer may be located to cover the first connection electrode and the second connection electrode. In addition, the first pixel electrode PE1 and the second pixel electrode PE2 may be located on the third insulating layer. The first pixel electrode PE1 may be connected to the first connection electrode through a contact hole penetrating (or, defined through) the third insulating layer. The second pixel electrode PE2 may be connected to the second connection electrode through a contact hole penetrating (or, defined through) the third insulating layer.

The first connection electrode may be connected to the first contact electrode SE1 or the second contact electrode DE1 through a contact hole penetrating (or, defined through) the second insulating layer IL2, and the second connection electrode may be connected to the third contact electrode SE2 or the fourth contact electrode DE2 through a contact hole penetrating (or, defined through) the second insulating layer IL2. For example, the first connection electrode may be formed through substantially a same method as the first contact electrode SE1 described with reference to FIG. 13 and may have substantially a same structure as the first contact electrode SE1. For example, the method (e.g., the method S100 of FIG. 1) according to an embodiment of this disclosure may be used in several embodiments where a metal pattern is filled in a contact hole. In addition, the method (e.g., the method S100 of FIG. 1) may be used in several embodiments where a metal pattern is formed on the substrate DSUB or on an insulating layer (e.g., the first insulating layer IL1, the second insulating layer IL2, and/or the like).

The display device (e.g., the display device DD of FIG. 11) according to embodiments may be applied to various electronic devices. An electronic device, according to several embodiments of the present disclosure, may include the above-described display device, and may further include a module or device having other additional functions in addition to the display device.

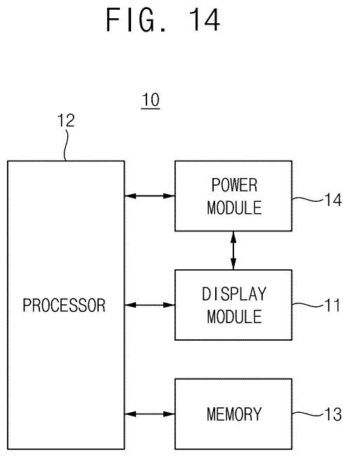

FIG. 14 is a block diagram illustrating an electronic device according to several embodiments of the present disclosure.

Referring to FIG. 14, an electronic device 10 according to embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

In several embodiments, data information necessary for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of components of the electronic device 10 described above may be included in the display device according to the above-described embodiments. In some embodiments, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

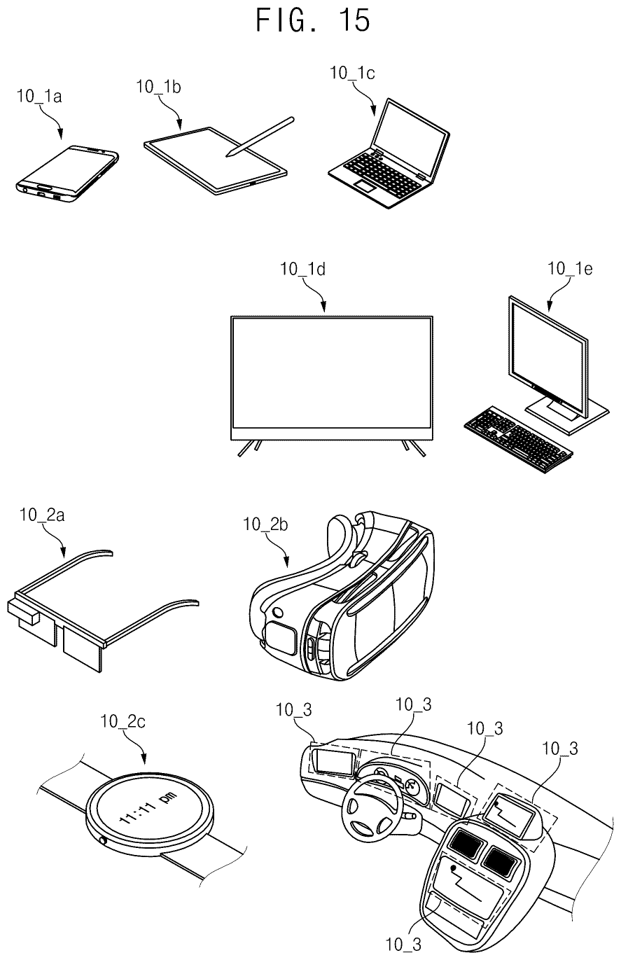

FIG. 15 shows examples of electronic devices, according to various embodiments.

Referring to FIG. 15, various electronic devices to which display devices according to several embodiments may be applied are shown. Examples of such electronic devices may include not only electronic devices for image display such as a smartphone 10_1a, a tablet computer 10_1b, a laptop computer 10_1c, a TV 10_1d, a computer monitor 10_1e, and/or the like, but also wearable electronic devices including display modules such as a smart glass 10_2a, a head mounted display 10_2b, a smart watch 10_2c, and/or the like. In an embodiment, an electronic device including a display module may be applied to a vehicle, as illustrated in FIG. 15. For example, the electronic device 10_3 may be applied to a dashboard, center fascia, etc. of a vehicle, or may be applied to a CID (Center Information Display) placed on a dashboard of a vehicle, or a room mirror display replacing a side mirror, and/or the like.

The present disclosure can be applied to various display devices. For example, the present disclosure is applicable to various display devices such as display devices for vehicles, ships and aircraft, portable communication devices, display devices for exhibition or information transmission, medical display devices, and/or the like.

Those skilled in the art will recognize that the present disclosure can be practiced in other specific ways without departing from its technical spirit or essential characteristics. Therefore, the described embodiments should be regarded as illustrative rather than being restrictive in all aspects. Although embodiments of the present disclosure have been described with reference to the accompanying drawings, the disclosure is not necessarily limited to these embodiments and may be implemented in various forms.

What is claimed is:

1. A method of forming a metal pattern, the method comprising:
forming a resin pattern on a substrate;
immersing the substrate in a solution; and
placing a magnet under the substrate.

2. The method of claim 1, wherein the solution includes a solvent and metal nanoparticles dispersed in the solvent.

3. The method of claim 2, wherein at least some of the metal nanoparticles penetrate into the resin pattern when the magnet is placed under the substrate.

4. The method of claim 2, wherein each of the metal nanoparticles includes at least one metal selected from a group consisting of iron (“Fe”), cobalt (“Co”), and nickel (“Ni”).

5. The method of claim 2, wherein each of the metal nanoparticles is coated with a surfactant.

6. The method of claim 1, wherein a metal pattern is formed on the resin pattern by placing the magnet under the substrate.

7. The method of claim 1, further comprising:
removing the magnet from under the substrate, wherein
a metal layer is formed on the substrate by placing the magnet, and a portion of the metal layer spaced apart from the resin pattern in a plan view is removed by removing the magnet from under the substrate.

8. The method of claim 1, further comprising:
forming an insulating layer on the substrate, wherein
the forming of the resin pattern on the substrate includes forming the resin pattern on the insulating layer.

9. The method of claim 8, wherein the forming of the resin pattern on the insulating layer includes:
forming a contact hole in the insulating layer; and
forming the resin pattern, wherein the resin pattern fills at least a portion of the contact hole.

10. The method of claim 9, wherein a metal pattern is formed to fill at least a portion of the contact hole by placing the magnet under the substrate.

11. A display device, comprising:
a first insulating layer on a substrate, the first insulating layer including a first contact hole;
a resin pattern filling at least a portion of the first contact hole;
a first contact electrode covering the resin pattern;
a second insulating layer covering the first contact electrode; and
a light-emitting element on the second insulating layer.

12. The display device of claim 11, wherein the first contact electrode covers an upper surface of the resin pattern disposed in at least the portion of the first contact hole.

13. The display device of claim 11, wherein the first contact electrode is fixed on the substrate using the resin pattern.

14. The display device of claim 13, wherein the substrate includes a first contact area, and the first contact electrode is fixed to the first contact area using the resin pattern.

15. The display device of claim 11, wherein at least some of metal nanoparticles included in the first contact electrode penetrate into the resin pattern.

16. The display device of claim 15, wherein each of the metal nanoparticles includes at least one metal selected from a group consisting of iron (“Fe”), cobalt (“Co”), and nickel (“Ni”).

17. The display device of claim 15, wherein each of the metal nanoparticles is coated with a surfactant.

18. An electronic device, comprising:
a display device;
a processor configured to drive the display device; and
a memory configured to store data information, wherein the display device comprises:
a first insulating layer on a substrate, the first insulating layer including a first contact hole;
a resin pattern filling at least a portion of the first contact hole;
a first contact electrode covering the resin pattern;
a second insulating layer covering the first contact electrode; and
a light-emitting element on the second insulating layer.

19. The electronic device of claim 18, wherein the first contact electrode is fixed on the substrate using the resin pattern.

20. The electronic device of claim 18, wherein at least some of metal nanoparticles included in the first contact electrode penetrate into the resin pattern.
